(19) United States
(12) Patent Application Publication
(10) Pub. No.: US 2016/0155792 A1
(43) Pub. Date: Jun. 2, 2016

(54) OLED DISPLAY DEVICE

(71) Applicant: EverDisplay Optronics (Shanghai) Limited, Shanghai City (CN)

(72) Inventors: Huannan WANG, Shanghai City (CN); Yu-Hsiung FENG, Shanghai City (CN); Lina XIAO, Shanghai City (CN)

(21) Appl. No.: 14/951,781

(22) Filed: Nov. 25, 2015

(30) Foreign Application Priority Data
Dec. 2, 2014 (CN) 201410723459.4

(51) Int. Cl. H01L 27/32; H01L 51/52; H01L 29/786

(52) U.S. Cl. CPC H01L 27/3276; H01L 27/3262; H01L 27/3265; H01L 27/3248; H01L 29/78672; H01L 27/3258; H01L 51/5218; H01L 27/3246; H01L 51/5234; H01L 2251/5315

(57) ABSTRACT

The disclosure discloses an organic light emitting diode (OLED) display device comprising: a substrate including a display area formed of a plurality of pixel structures; a plurality of first signal lines; a plurality of second signal lines; and a plurality of TFTs and a storage capacitor, disposed in each of the plurality of pixel structures, wherein the plurality of second signal lines include an initial signal line; a second end of the storage capacitor is formed of a first conduction layer, and a first end of the storage capacitor and the initial signal line are formed of a second conduction layer, and the second conduction layer is located above the first conduction layer. The OLED display device may prevent the initial signal line and the anode from being short circuited.

### CROSS REFERENCE TO RELATED APPLICATIONS

This application claims the priority to and the benefit of Chinese Patent Application No. 201410723459.4, filed Dec. 2, 2014 and entitled “OLED display device,” which is incorporated herein by reference in its entirety.

### TECHNICAL FIELD

The present disclosure relates generally to the technical field of organic light emitting diode (OLED) display, and particularly to an OLED display device.

### BACKGROUND

Organic light emitting diode (OLED) display device is divided into passive matrix organic light emitting diode (PMOLED) and active matrix organic light emitting diode (AMOLED). The AMOLED display device has a more complex manufacturing process compared with PMOLED display device.

FIG. 7 is a schematic diagram showing a sub-pixel circuit of an AMOLED display device. A skilled person in the art should understand that the AMOLED display device comprises a plurality of sub-pixel structures, and the circuit schematic diagram of the AMOLED display device also comprises a plurality of sub-pixel circuit schematic diagrams shown in FIG. 7, which is not illustrated for concise purpose.

As shown in FIG. 7, each sub-pixel circuit in the AMOLED display device includes a cathode K and a plurality of signal lines such as a data line Dm, a luminance anode signal line ELVDD, a scan line Sn+1, a scan line Sn, a scan line Sn−1, a luminance driving line En, an initial signal line Vin and a storage capacitor signal line (not shown). The signal lines transmit corresponding signals to the pixels at different timings from the periphery of the display area, with the cooperation of the TFTs and capacitors shown in FIG. 7, displaying different grey scales of OLED sub-pixels is achieved. That is, only by electrically connecting the signal lines to the sub-pixels from the periphery of the display area can it achieve the display function of the AMOLED display device.

The conventional sub-pixel is arranged as FIG. 1, referring to FIG. 1 and FIG. 7, in the above signal lines, the data line Dm and luminance anode signal line ELVDD are vertically-arranged signal lines, and the scan line Sn+1, scan line Sn, scan line Sn−1, luminance driving line En, the signal line of the storage capacitor C1 and the initial signal line Vin are horizontally-arranged signal lines.

To form the signal lines, the TFTs and capacitor structures in the AMOLED pixel structures, the semiconductor technology is adopted in the conventional manufacturing method, in which, a plurality of thin film structures such as a semiconductor layer, a first gate insulation layer, a first conduction layer (gate power supply layer 1), a second gate-insulation layer, a second conduction layer (gate power supply layer 2), a data line insulation layer, a third conduction layer (data line layer), a planarization layer (anode insulation layer), a fourth conduction layer (anode metal layer) and a pixel defining layer are deposited, and between the above deposition process structures such as signal lines, TFTs and capacitors in FIG. 1 are formed by defining certain patterns at required positions with semiconductor processes such as masking, exposing and etching.

In the above structure, the first direction data line Dm and the luminance anode signal line ELVDD are formed by the third conduction layer; the second direction scan line Sn+1, scan line Sn, scan line Sn−1 and luminance driving line En are formed by the first conduction layer; one end of the capacitor structure, which is second direction and extends out of the display area, and storage capacitor signal line are formed by the second conduction layer, while the initial signal line Vin which is also second direction is formed by the fourth conduction layer.

In addition, the semiconductor layer is mainly used for form channels in the TFTs; the first conduction layer not only forms the aforementioned scan lines and the luminance driving line En, but also forms the first gate of the TFTs and the other end of the capacitor structure. The fourth conduction layer not only forms the aforementioned initial signal line Vin, but also forms the anode structure of the OLED appliance; the pixel defining layer is located above the fourth conduction layer and forms a plurality of recesses for defining the positions of the sub-pixels, the bottoms of the recesses expose the anode defined by the fourth conduction layer, and the OLED material is formed on the anode of the recesses to form OLED sub-pixels.

With the high PPI (Pixel per inch) trend of the AMOLED display device, the importance of the pixel circuit layer design cooperating with the trend is increasing. However, high PPI means a reduction of each sub-pixel in area, which brings severer challenge to the layout of the signal lines, TFTs and capacitor structure of the sub-pixels. Further referring to FIG. 2 and FIG. 3, in order to facilitate illustration, FIG. 2 is a schematic diagram only showing the fourth conduction layer and pixel defining layer layout on the fourth conduction layer, and FIG. 3 is a partially sectional diagram taken along line I-I′ in FIG. 1. As shown in FIG. 2, the initial signal line Vin and the anode structure A of the OLED appliance are formed by the fourth conduction layer, and an opening O of the pixel defining layer located above the anode electrode A exposes the anode A. as shown in FIG. 3, an insulation layer 102, a data line metal layer 103, a planarization layer 104 and an anode metal layer 105 are formed above the semiconductor layer 101. The initial signal line Vin is located in the anode metal layer 105, the anode metal layer 105 is electrically connected to the semiconductor layer 101 via a contact hole H1. Thusly, the initial signal is horizontally transmitted by the initial signal line Vin from a periphery of the display area to the sub-pixels, and is conducted to the semiconductor layer 101 at below via the contact hole H1.

FIG. 2 shows problem encountered when the layout of the initial signal line is applied to the high PPI pixel structure. As shown in FIG. 2, on the one hand, since the pixel area is reduced due to the increase of PPI, the initial signal line and the anode which are formed on the fourth conduction layer contact each other due to their over-small area, thus the signal may be short-circuited. On the other hand, the opening of the pixel defining layer may be further reduced for preventing the short circuit between the initial signal line and the anode by reducing the area of the anode, however, this would lead to reduce the pixel luminance area and not benefit for image display.

### SUMMARY

An object of the disclosure is to provide an AMOLED display device with reasonable pixel layout design to avoid signal short-circuit between the initial signal line and anode due to over-small area, to overcome the deficiency of the prior art.

The disclosure discloses an organic light emitting diode (OLED) display device comprising:

a substrate including a display area formed of a plurality of pixel structures and a periphery area outside the display area;

a plurality of first signal lines, extending in a first direction from the periphery area to the plurality of pixel structures for transmitting multiple kinds of signals to the plurality of pixel structures;

a plurality of second signal lines, extending in a second direction from the periphery area to the plurality of pixel structures for transmitting multiple kinds of signals to the plurality of pixel structures, wherein the second direction is vertical to the first direction and the plurality of second signal lines including an initial signal line; and

a plurality of TFTs and a storage capacitor, disposed in each of the plurality of pixel structures,

wherein a second end of the storage capacitor is formed of a first conduction layer, and a first end of the storage capacitor and the initial signal line are formed of a second conduction layer, and the second conduction layer is located above the first conduction layer.

In the OLED display device of the disclosure, the initial signal line and the first end of the storage capacitor are arranged in the same metal layer, and the metal layer is connected to the semiconductor layer via the contact hole, which prevents the short circuit between the initial signal line and the anode, and could increase luminance area of the OLED without changing the size of the pixel, thusly preserving defining space for the OLED luminance efficiency.

The foregoing summary is not intended to summarize each potential embodiment or every aspect of the present disclosure.

### BRIEF DESCRIPTION OF THE DRAWINGS

FIG. 1 is a schematic diagram showing the pixel layout design in the prior art.

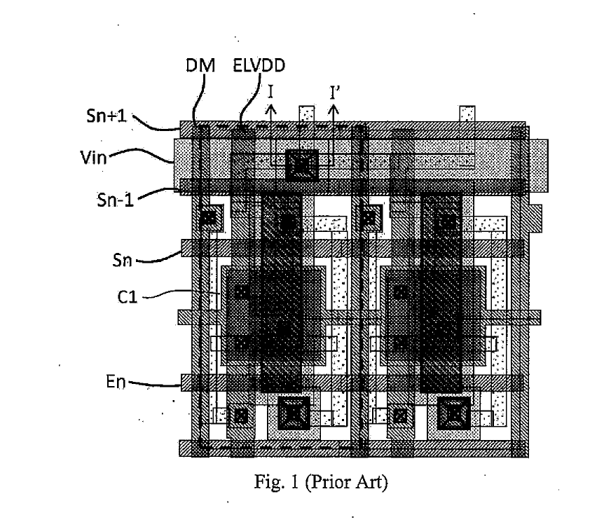

FIG. 2 is a schematic diagram showing the fourth conduction layer and the pixel defining layout layer on the fourth conduction layer.

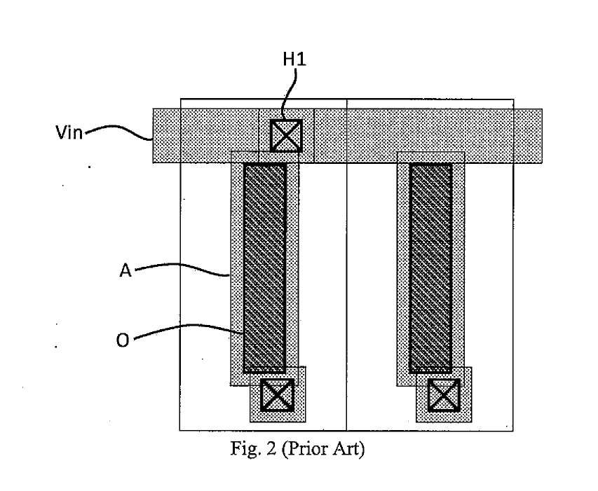

FIG. 3 is a partial sectional diagram taken along line I-I′ in FIG. 1.

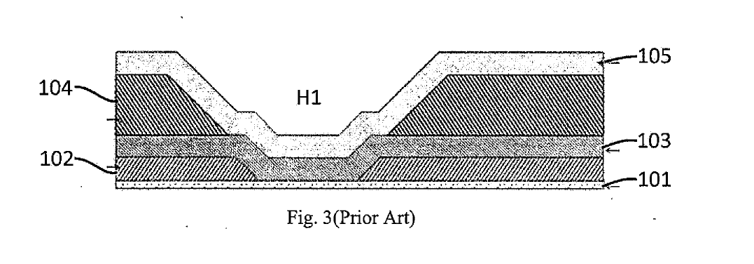

FIG. 4 is a schematic diagram showing the pixel layout design of the AMOLED display device in an embodiment of the disclosure.

FIG. 5 is a schematic diagram showing the projection of the pixel layout in FIG. 4 on the second conduction layer.

FIG. 6 is a partial sectional diagram taken along line II-II′ in FIG. 4.

FIG. 7 is a schematic diagram showing the sub-pixel circuit of the AMOLED display device.

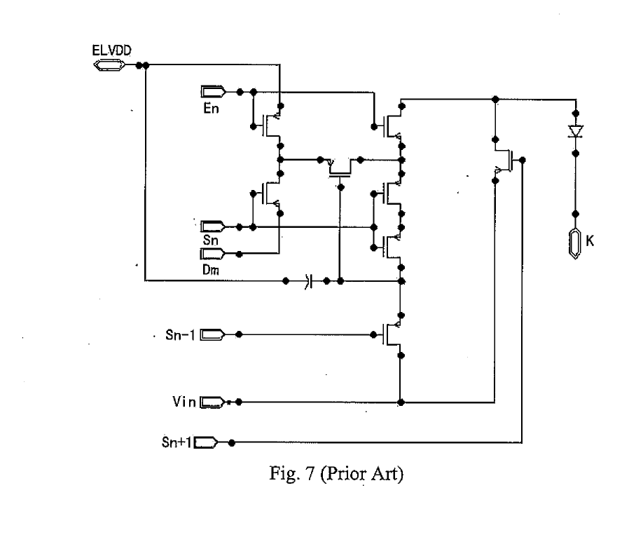

Specific embodiments in this disclosure have been shown by way of example in the foregoing drawings and are hereinafter described in detail. The figures and written description are not intended to limit the scope of the inventive concepts in any manner. Rather, they are provided to illustrate the inventive concepts to a person skilled in the art by reference to particular embodiments.

### DETAILED DESCRIPTION

Hereinafter, implementations of methods and apparatuses for processing short messages according to the embodiments of the present disclosure will be described in detail in conjunction with the drawings.

In an embodiment of the disclosure, the OLED display device includes:

a substrate including a display area formed of a plurality of pixel structures and a periphery area outside the display area;

a plurality of first signal lines, extending in a first direction from the periphery area to the plurality of pixel structures for transmitting multiple kinds of signals to the plurality of pixel structures;

a plurality of second signal lines, extending in a second direction from the periphery area to the plurality of pixel structures for transmitting multiple kinds of signals to the plurality of pixel structures, wherein the second direction is vertical to the first direction and the plurality of second signal lines including an initial signal line; and

a plurality of TFTs and a storage capacitor, disposed in each of the plurality of pixel structures.

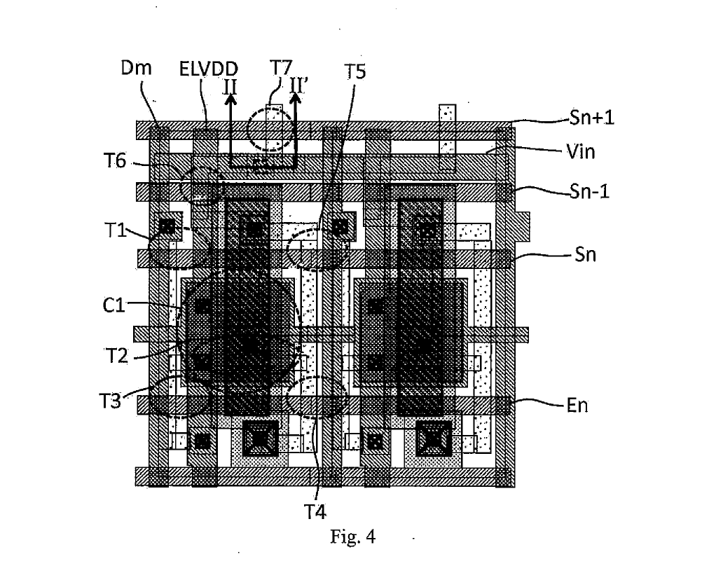

FIG. 4 is a schematic diagram showing the pixel layout of the AMOLED display device in an embodiment of the disclosure, which shows pixel layout with two pixel structures. As shown in FIG. 4, the scan line Sn+1, scan line Sn, scan line Sn−1, the luminance driving line En and the initial signal line Vin are arranged in a second direction, that is, horizontally, while data line Dm and the luminance anode signal line ELVDD are arranged in a first direction vertical to the second direction, that is, vertically, the initial signal line Vin is used to provide initial signal to the pixel structures to reset any of the capacitor of the pixel structures.

In the pixel structures at the left side of FIG. 4, TFTs T1, T2, T3, T4, T5, T6 and T7 and a storage capacitor C1 are disposed.

A semiconductor technology is used to form the above signal lines, the TFTs T1, T2, T3, T4, T5, T6 and T7 and the storage capacitor C1 of the pixel structures of the OLED in the disclosure. In which, a multi-layer film structure including a semiconductor layer, a first gate insulation layer, a first conduction layer (gate power source layer 1), a second gate insulation layer, a second conduction layer (gate power supply layer 2), a data line insulation layer, a third conduction layer (data line layer), a planarization layer (anode insulation layer), a forth conduction layer (anode metal layer) and a pixel defining layer are deposited, and signal lines and TFTs T1, T2, T3, T4, T5, T6 and T7 and the storage capacitor C1, etc., in FIG. 4 are formed by defining certain patterns at predetermined positions with semiconductor technologies such as masking, exposing and etching among the processes.

The storage capacitor C1 has a first end and a second end, the first end of which is formed of the second conduction layer, and the second end of which is formed of the first conduction layer. The second conduction layer is located above the first conduction layer, and the second conduction layer and the first conduction layer are separated by the second gate insulation layer.

Both the first conduction layer and the second conduction layer may be metal layers, which may be formed of Mo or Mo—Al—Mo lamination.

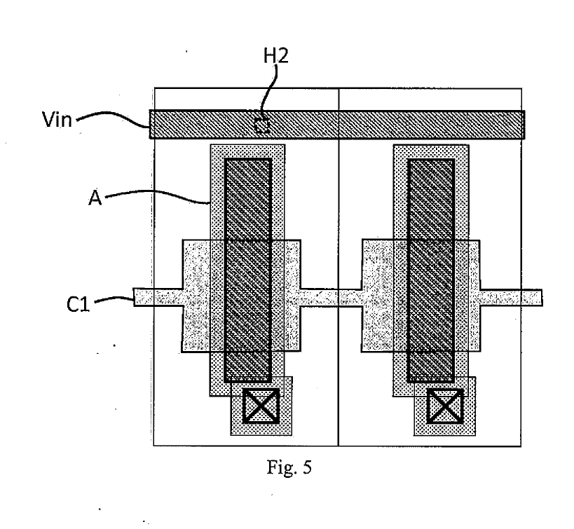

The initial signal line Vin and the first end of the storage capacitor C1 are formed by the same metal layer, i.e., the second conduction layer. FIG. 5 is a schematic diagram showing the projection of the pixel layout in FIG. 4 in the second conduction layer. As shown in FIG. 5, both the initial signal line Vin and the first end of the storage capacitor C1 are formed of the second conduction layer, while the anode A is formed of an anode metal layer which is in different layer from the second conduction layer. Since the anode metal layer and the second conduction layer are in different planes, it is impossible to have a short circuit problem due to overlapped initial signal line Vin and the anode A caused by high PPI, at the same time, it is unnecessary to reduce luminance area for preventing short circuit under high PPI, thusly the luminance effect of the OLED may be designed flexibly in certain extent.

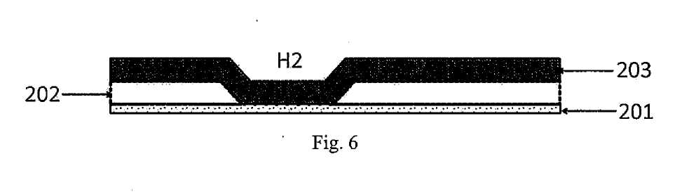

FIG. 6 is a partial sectional view taken along line II-IP in FIG. 4. The OLED display device further includes a semiconductor layer 201 and a first insulation layer 202 on the substrate. The first insulation layer 202 is located between the semiconductor layer 201 and the second conduction layer 203 on which the initial signal line is located to perform insulation function. In detail, the first insulation layer 202 is formed of the first gate insulation layer and the second gate insulation layer.

The first conduction layer (not shown) is located under the second conduction layer 203 such as at the first insulation layer 202, thereby dividing a part area of the first insulation layer 202 into an upper layer and a lower layer. The lower layer is a first gate insulation layer, and the upper layer is a second gate insulation layer. The scan line Sn+1, scan line Sn, Scan line Sn−1 and the luminance driving line En are formed by the first conduction layer and located above the first gate insulation layer.

The semiconductor layer 201 may be a polycrystalline silicon layer which may include channels, source, drain and layout of the TFT. The first insulation layer 202 may be a silicon oxide layer, silicon nitride layer or lamination of silicon oxide layer and silicon nitride layer.

To connect the initial signal line and the semiconductor layer 201, a contact hole H2 may be formed at the first insulation layer 202. The contact hole H2 passes through the first insulation layer 202 and exposes the semiconductor layer disposed at the below, thereby making the initial signal line electrically connected to the semiconductor layer 201 via the contact hole H2.

In addition, the initial signal lines of two neighboring pixel structures may be electrically connected to the semiconductor layer of two neighboring pixel structures via the same contact hole, therefore, the whole horizontal pixel could be connected together via the second conduction layer with the arrangement above.

The data line and the luminance anode signal line ELVDD may be formed by data line metal layer, the data line metal layer is located above the second conduction layer 203, at the same time a second insulation layer is disposed between the data line metal layer and the second conduction layer 203.

A planarization layer is located above the data line metal layer, which is an organic material layer. By coating thicker organic material, recesses such as contact holes could be filled to achieve flatness.

An anode metal layer is further provided above the planarization layer, which forms the anodes of the pixel structures. The anode metal layer may be a reflect layer, thusly making the anodes of the pixel structures a reflect electrode.

A pixel defining layer is further provided above the anode metal layer, which includes an opening, the bottom of the opening exposes the anodes of the pixel structures.

In the opening of the pixel defining layer, organic luminance material is further disposed, which contacts the anode to form the organic luminance functioning layer.

A transparent conduction layer is further disposed above the pixel defining layer and the organic luminance material, which forms the cathodes of the pixel structures so as to constitute a luminance unit together with the anode and the organic luminance material.

To sum up, in the OLED display device, the initial signal line and the first end of the storage capacitor are arranged in the same metal layer, and the metal layer is connected to the semiconductor layer via the contact hole, which prevents the short circuit between the initial signal line and the anode, and could increase luminance area of the OLED without changing the size of the pixel, thusly preserving defining space for the OLED luminance efficiency.

One of ordinary skill in the art will understand that the modules in the apparatus of the embodiment may be distributed in the apparatus of the embodiment, or may be correspondingly varied to be positioned in one or more apparatuses other than that of the embodiment. The aforementioned modules of the embodiment may be combined as one module, or may be further divided into a plurality of sub-modules. The aforementioned serial numbers of the embodiments are only for illustrative purpose, not relating to the superiority or inferiority of the embodiments.

What is claimed is:

1. An organic light emitting diode (OLED) display device comprising:
a substrate including a display area formed of a plurality of pixel structures and a periphery area outside the display area;
a plurality of first signal lines, extending in a first direction from the periphery area to the plurality of pixel structures for transmitting multiple kinds of signals to the plurality of pixel structures;
a plurality of second signal lines, extending in a second direction from the periphery area to the plurality of pixel structures for transmitting multiple kinds of signals to the plurality of pixel structures, wherein the second direction is vertical to the first direction and the plurality of second signal lines including an initial signal line; and
a plurality of TFTs and a storage capacitor, disposed in each of the plurality of pixel structures,
wherein a second end of the storage capacitor is formed of a first conduction layer, and a first end of the storage capacitor and the initial signal line are formed of a second conduction layer, and the second conduction layer is located above the first conduction layer.

2. The OLED display device according to claim 1, wherein the initial signal line is used for providing an initial signal to the plurality of pixel structures to reset any of the storage capacitor of the plurality of pixel structures.

3. The OLED display device according to claim 1, wherein the first conduction layer and the second conduction layer are respectively formed of Mo or Mo—Al—Mo lamination.

4. The OLED display device according to claim 1, wherein the substrate further comprises a semiconductor layer and a first insulation layer located between the semiconductor layer and the initial signal line, the first insulation layer including a contact hole, and the initial signal line of the plurality of pixel structures is electrically connected to the semiconductor layer via the contact hole.

5. The OLED display device according to claim 4, wherein the semiconductor layer is formed of polycrystalline silicon.

6. The OLED display device according to claim 4, wherein the first insulation layer is a silicon oxide layer, a silicon nitride layer or a lamination of silicon oxide and silicon nitride.

7. The OLED display device according to claim 4, wherein the initial signal lines of two neighboring pixel structures are electrically connected to the semiconductor layer of the two neighboring pixel structures via a same contact hole.

8. The OLED display device according to claim 1, wherein the first signal lines include a data line and a luminance anode signal line (ELVDD).

9. The OLED display device according to claim 8, wherein the data line and the luminance anode signal line (ELVDD) are formed of a data line metal layer, the data line metal layer is located above the second conduction layer, and a second insulation layer is located between the data line metal layer and the second conduction layer.

10. The OLED display device according to claim 8, further comprising a planarization layer located above the data line metal layer, and the planarization layer is formed of an organic material.

11. The OLED display device according to claim 10, further comprising an anode metal layer located above the planarization layer, and anodes of the plurality of pixel structures are formed of the anode metal layer.

12. The OLED display device according to claim 11, wherein the anode metal layer is a reflection layer, and the anodes of the plurality of pixel structures are reflection electrodes.

13. The OLED display device according to claim 12, further comprising a pixel defining layer located above the anode metal layer, and the pixel defining layer includes an opening to expose the anodes of the plurality of pixel structures.

14. The OLED display device according to claim 13, further comprising an organic luminance material received in the opening of the pixel defining layer, wherein the organic luminance material contacts the anode.

15. The OLED display device according to claim 14, further comprising a transparent conduction layer located above the pixel defining layer and the organic luminance material, wherein a cathode of each of the plurality of pixel structures is formed of the transparent conduction layer.

16. The OLED display device according to claim 1, wherein the second signal lines further include a plurality of scan lines, and the scan lines are formed of the first conduction layer.

17. The OLED display device according to claim 1, wherein the second signal lines further include a luminance driving line, the luminance driving line is formed of the first conduction layer.
